(19) United States
(12) Patent Application Publication
(10) Pub. No.: US 2017/0040285 A1
(43) Pub. Date: Feb. 9, 2017

(54) WAFER PLANARIZATION METHOD

(71) Applicants: STMicroelectronics (Crolles 2) SAS, Crolles (FR); Commissariat A L'Energie Atomique et aux Energies Alternatives, Paris (FR)

(72) Inventors: Francois Guyader, Montbonnot (FR); Emmanuel Gourvest, Voiron (FR); Patrick Gros D'aillon, Biviers (FR)

(73) Assignees: STMicroelectronics (Crolles 2) SAS, Crolles (FR); Commissariat A L'Energie Atomique et aux Energies Alternatives, Paris (FR)

(21) Appl. No.: 15/225,164

(22) Filed: Aug. 1, 2016

(30) Foreign Application Priority Data
Aug. 7, 2015 (FR) 1557609

(51) Int. Cl. H01L 23/00; H01L 21/78; H01L 27/146

(52) U.S. Cl. CPC H01L 24/83; H01L 27/14685; H01L 27/14687; H01L 27/1462; H01L 24/94; H01L 21/78; H01L 24/27; H01L 24/29; H01L 27/14643; H01L 2224/83031; H01L 27/1464; H01L 2224/83894; H01L 2224/27845; H01L 2224/29082

(57) ABSTRACT

A planar layer of a selected material is formed on a surface of a wafer exhibiting recesses. The formation process including the steps of: a) depositing a first layer of the selected material on the surface; b) performing a chemical mechanical polishing of the first layer; c) depositing a second layer of the selected material on the first layer; and d) performing a chemical mechanical polishing of the second layer.

### PRIORITY CLAIM

This application claims the priority benefit of French Application for Patent No. 1557609, filed on Aug. 7, 2015, the contents of which are hereby incorporated by reference.

### TECHNICAL FIELD

The present disclosure relates to the forming of electronic components inside and on top of a semiconductor wafer, and more particularly a wafer planarization method.

### BACKGROUND

During the manufacturing of certain electronic components such as back-side illuminated CMOS image sensors, at a step where the components of a same wafer have not been separated into individual chips yet, the wafer portion which is located at the back of the components is desired to be removed. To achieve this, to be able to handle the wafer during back side chemical dissolution and/or grinding steps, a handle is bonded to the front surface of the wafer. The handle is for example a silicon wafer having the same diameter as the wafer, the surface to be bonded being covered with oxide. During the separation into chips, the handle is sawn at the same time as the wafer. A molecular bonding of the handle to the wafer is desired to be performed, and for this purpose, any unevenness, due to recesses or raised areas, of the wafer surface, should not exceed a 10-nm height.

FIG. 1 is a partial simplified cross-section view of the upper surface of a silicon wafer 1 at a step preceding the bonding of a handle. At surface 3 of the wafer, there exist recesses 5 resulting from the forming of structures, not shown, present under the surface, for example, of successive metallization layers separated by insulators. The recesses or raised areas have variable dimensions which may be greater than 100 nm and even range up to 100 μm. Their depth may range from 10 to 200 nm. Thus, a planarization of the wafer is necessary before performing the molecular bonding.

FIGS. 2A and 2B are simplified cross-section views illustrating the wafer of FIG. 1 after successive steps of a conventional planarization method.

In FIG. 2A, a silicon oxide layer 7 having a thickness in the range from 0.5 to 5 μm has been deposited. Layer 7 follows the surface unevenness of the wafer and thus recesses 5 are reproduced in the form of recesses 9 at surface 11 of layer 7.

In FIG. 2B, a chemical mechanical polishing step (currently called CMP in the art) of layer 7 has been carried out, leaving in place a residual silicon oxide layer 7a. Surface 13 of layer 7a does not reproduce recesses 5. But certain recesses 15 having an attenuated depth, still greater, however, than 10 nm, may remain in surface 13 of layer 7a.

There thus is a need to improve planarization methods.

### SUMMARY

Thus, an embodiment provides a method of forming a planar layer of a selected material on a surface of a wafer exhibiting recesses, the method comprising the steps of: a) depositing a first layer of the selected material on the surface; b) performing a chemical mechanical polishing of the first layer; c) depositing a second layer of the selected material on the first layer; and d) performing a chemical mechanical polishing of the second layer.

According to an embodiment, the depth of said recesses is in the range from 10 to 200 nm, the thicknesses of the first and second layers being in the range from 1 to 3 μm, and each polishing step removing a thickness in the range from 0.7 to 1.2 μm, whereby the planar layer has a surface roughness smaller than 10 nm.

According to an embodiment, the method further comprises, after d), a step of molecular bonding between the wafer and a handle.

According to an embodiment, the method further comprises a step of sawing the wafer into chips, portions of the wafer surface located between the chips being recessed.

According to an embodiment, the wafer is made of silicon and the selected material is silicon oxide.

According to an embodiment, the chips are back-side illuminated CMOS image sensors.

An embodiment provides an electronic chip wherein structures comprising metallization layers separated by insulators are covered with a first layer of a material, a second layer of the material covering the first layer, a handle being bonded by molecular bonding to the second layer, wherein an unevenness present at the surface of said structures, and the second layer has a roughness lower than 10 nm.

According to an embodiment, the depth of said unevenness is in the range from 10 to 200 nm.

According to an embodiment, the chip is a back-side illuminated CMOS image sensor.

### BRIEF DESCRIPTION OF THE DRAWINGS

The foregoing and other features and advantages will be discussed in detail in the following non-limiting description of specific embodiments in connection with the accompanying drawings, wherein:

FIG. 1, already described, is a partial simplified cross-section view of the upper surface of a wafer;

FIGS. 2A and 2B, already described, are simplified cross-section views illustrating a planarization method;

FIG. 3 is a photograph of a portion of the surface of a wafer after application of the method illustrated in FIGS. 2A and 2B;

FIGS. 4A, 4B, 4C, and 4D are partial simplified cross-section views illustrating successive steps of an example of a planarization method; and

FIGS. 5A and 5B show numbers of defects per wafer, for wafers manufactured by the method illustrated in FIGS. 2A and 2B and for wafers manufactured by the method illustrated in FIGS. 4A to 4D.

### DETAILED DESCRIPTION

The same elements have been designated with the same reference numerals in the different drawings and, further, the various drawings are not to scale. For clarity, only those elements which are useful to the understanding of the described embodiments have been shown and are detailed. In particular, structures such as metallization layers formed under the wafer surface are not shown.

In the following description, when reference is made to terms qualifying the relative position, such as term “upper”, reference is made to the position of the concerned elements in the drawings. Unless otherwise specified, expression “in the order of” means to within 10%, preferably to within 5%.

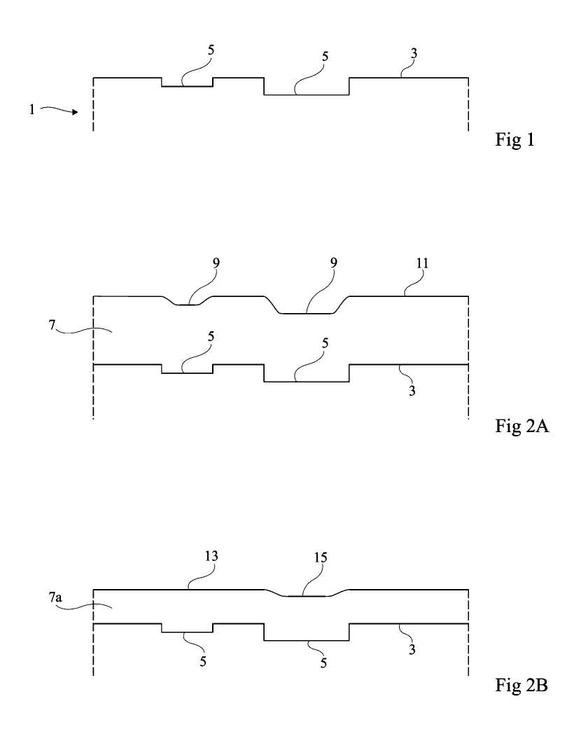

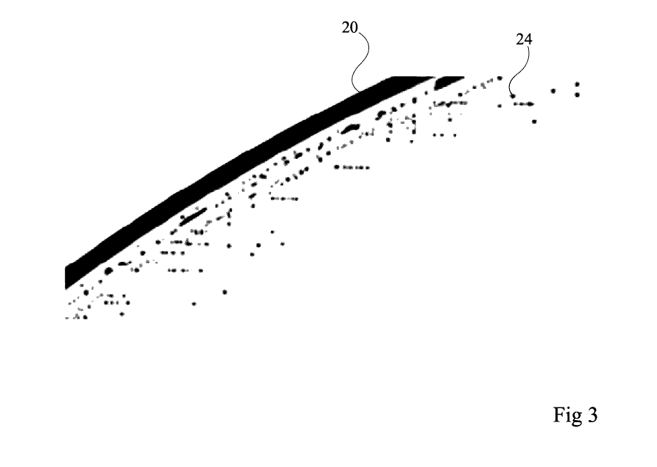

FIG. 3 is a photograph of a portion of the surface of a wafer after application of the method illustrated in FIGS. 2A and 2B comprising depositing a silicon oxide layer, and then polishing it by CMP.

CMP polishing comprises placing the wafer surface in contact with the surface of a polishing pad in the presence of an aqueous solution comprising chemical compounds and abrasive particles, for example, made of silicon oxide. The wafer and the pad are moved relative to each other. As an example, the diameter of the pad is greater than the wafer diameter, and the wafer is displaced according to an orbital motion against the pad.

The photographed portion is located at the periphery of the wafer. A handle has been attached to the surface, and the photograph, obtained by scanning acoustic microscopy, shows in black the locations where the connection between the wafer and the handle is defective. The portions where the molecular bonding is of good quality appear in light shade, as well as the portions located outside of the wafer.

The edge of the wafer is visible in the form of a black stripe 20. The presence of defects 24, by a greater number closer to the wafer periphery, can be observed. Such defects correspond to height irregularities greater than 10 nm in the surface obtained after the polishing step.

The conventional method comprising depositing and then polishing by CMP an oxide layer appears to be insufficient to decrease the height of the surface unevennesses, due to recesses or raised areas, of a silicon wafer where a handle is desired to be bonded by molecular bonding. To lower the surface roughness of the surface below 10 nm, which is preferable for the molecular bonding, it may be attempted to optimize this conventional method. For example, the thickness of the deposited layer may be increased. However, this thickness is in practice limited to approximately 5 μm. It may also be desired to increase the thickness removed during the polishing step. However, in this case, modifications of the surface state of the layer occur, which prevent carrying on the polishing operation beyond a removed thickness in the range from 2 to 3 μm.

Thus, whatever the way of implementing a conventional CMP planarization method on the uneven surface of a wafer, an unevenness, due to recesses or raised areas, having a height exceeding 10 nm may remain at the surface of the oxide layer. At the level of such unevenness, defects may appear in the molecular bonding of the handle to the oxide layer. Such defects appear to be mainly located at the wafer periphery.

At the time when the handle is bonded, the wafer, which contains electronic components, has not been sawn into individual chips yet. At the wafer surface the portions located between the components, where the sawing will be performed, happen to be recessed. Such recesses are due to the component manufacturing method. They have a depth in the range from 100 to 200 nm, a width in the range from 10 to 100 μm, and a length which may range up to the value of the wafer diameter. The recesses may remain at the surface of the oxide layer after the layer polishing step, and risk causing defects in the molecular bonding of the handle. The inventors have observed that the passing of a sawing tool in the defects is capable of creating cracks damaging the surrounding chips.

This is why another method enabling to lower the roughness of the surface of a wafer to less than 10 nm is desired, this method being efficient in the central portions as well as in the peripheral portions of the wafer. Roughness designates the recesses of a surface measured with respect to the mean surface locally considered as a plane: the term “depth” will here be used.

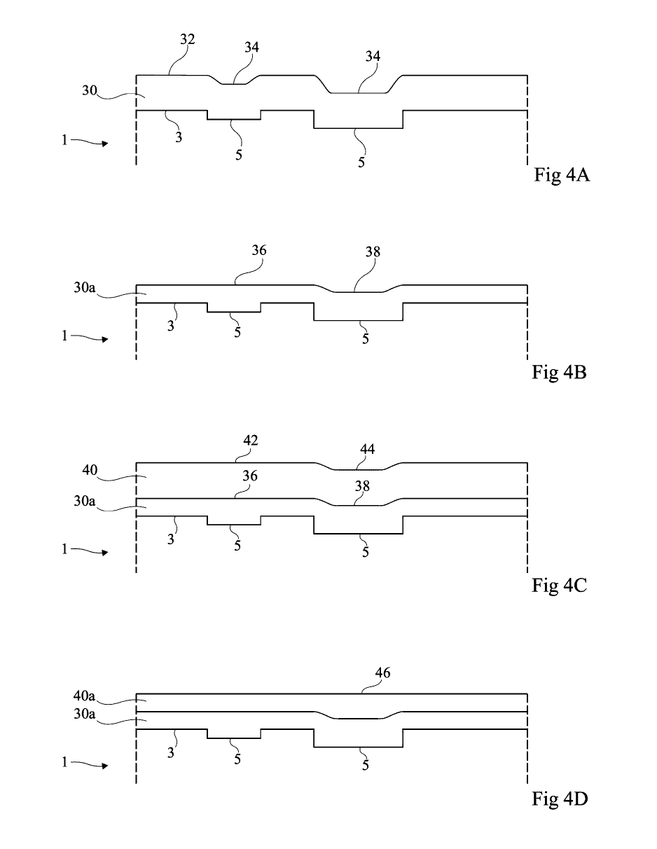

FIGS. 4A to 4D are simplified cross-section views illustrating successive steps of a planarization method applied to a wafer having an uneven upper surface.

In FIG. 4A, a silicon wafer 1 has an upper surface 3 comprising unevenness 5, due to recesses or raised areas, of variable width in the range from some hundred nanometers to a few hundreds of micrometers, and depths in the range from 10 to 200 nm. A first silicon oxide 30 is deposited on the upper surface of the wafer. The thickness of oxide layer 30 is for example in the range from 1 to 3 μm. Layers 30 follows the unevenness of surface 3 of wafer 1, and its surface 32 exhibits unevenness 34 due to recesses or raised areas.

In FIG. 4B, a first step of chemical mechanical polishing (CMP) of the upper surface of wafer 1 is carried out. This step is carried out to remove the upper portion of layer 30 down to a thickness for example in the range from 0.7 to 1.2 μm and to leave in place a residual layer 30a on the upper surface. At locations where recesses 5 of the wafer surface have significant widths and depths, there remain on surface 36 of layer 30a an unevenness 38, due to recesses or raised areas, having an attenuated depth with respect to that of recesses 5. Such defects especially appear at the wafer periphery.

In FIG. 4C, a second layer 40, preferably another silicon oxide layer, is deposited on surface 36 of layer 30a. The thickness of layer 40 is for example in the range from 1 to 3 μm. The surface of layer 40 follows the unevenness of surface 36 of layer 30a, and in particular recesses 38 to produce recesses 44.

In FIG. 4D, a second step of chemical mechanical polishing (CMP) of the upper surface of the wafer is carried out. This step is carried out to remove the upper portion of layer 40 down to a thickness for example in the range from 0.7 to 1.2 μm and to leave in place a residual layer 40a on layer 30a.

Measurements performed by the inventors show that the second polishing step decreases the roughness of surface 46 of layer 40a down to less than 10 nm.

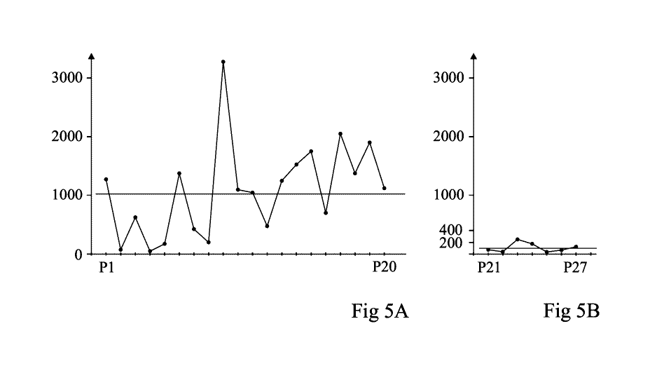

FIGS. 5A and 5B are graphs showing numbers of defects per wafer for various wafers. FIG. 5A shows the numbers of defects of twenty wafers P1 to P20 manufactured by the method implementing a single layer deposition and a single polishing. FIG. 5B shows numbers of defects of seven wafers P21 to P27 manufactured by the method comprising the deposition and the polishing of a first layer, followed by the deposition and the polishing of a second layer. The defects are counted after bonding of a handle onto each wafer. Lines have been drawn between the points corresponding to each wafer, to make the visualization easier.

In FIG. 5A, the number of defects observed after the planarization method using a single layer and a single polishing may range up to more than 3,000, and is in average greater than 1,000. In FIG. 5B, the number of defects is at most in the order of 200, and is in average lower than 100. Thus, as compared with the conventional method, the method comprising depositing and polishing a first layer and then depositing and polishing a second layer enables to decrease approximately by a factor ten the number of defects observed on the wafers. According to an additional advantage, it has been observed that the defects located towards the inside of the wafer are mainly suppressed, which increases the surface area of the defect-free wafer portion.

It should be noted that this result is obtained even while the sum of the thicknesses of the two successively-deposited layers may be in the order of the thickness of the single layer deposited in the conventional method, and the sum of the thicknesses removed by polishing of the two layers may be in the order of the thickness removed from the single layer.

Specific embodiments have been described. Various alterations, modifications, and improvements will occur to those skilled in the art. In particular, in the steps described in relation with FIGS. 3A and 3D, although the deposited layers 30 and 40 are silicon oxide layers, other materials may be used.

Although specific thicknesses of deposited layers and specific thicknesses removed by polishing have been detailed in the described embodiment, other variations are possible, using other thicknesses, for example, adapted to other dimensions of surface unevenness of the wafer.

Further, although the above-described method is applied to a silicon wafer, it should be clear that a similar method may be used to planarize the surface of wafers of other types of materials.

Such alterations, modifications, and improvements are intended to be part of this disclosure, and are intended to be within the spirit and the scope of the present invention. Accordingly, the foregoing description is by way of example only and is not intended to be limiting. The present invention is limited only as defined in the following claims and the equivalents thereto.

1. A method of forming a planar layer of a selected material on a surface of a wafer exhibiting recesses, the method comprising the steps of:
a) depositing a first layer of the selected material on the surface;
b) performing a chemical mechanical polishing of the first layer to produce a polished first layer;
c) depositing a second layer of the selected material on the polished first layer; and
d) performing a chemical mechanical polishing of the second layer to produce a polished second layer.

2. The method of claim 1, wherein a depth of said recesses is in a range from 100 to 200 nm, a thicknesses of each of the first and second layers is in a range from 1 to 3 μm, and each step b) and d) removes a thickness in a range from 0.7 to 1.2 μm, whereby the planar layer has a surface roughness lower than 10 nm.

3. The method of claim 1, further comprising, after step d), a step of molecular bonding between the planar layer of the wafer and a handle.

4. The method of claim 3, further comprising a step of sawing the wafer into chips, portions of the surface of the wafer located between the chips being recessed.

5. The method of claim 1, wherein said wafer is made of silicon and the selected material is silicon oxide.

6. The method of claim 4, wherein the chips are back-side illuminated CMOS image sensors.

7. An electronic chip, comprising:
a first layer of a material covering an upper surface of structures comprising metallization layers separated by insulators,
a second layer of the material covering the first layer, and
a handle bonded by molecular bonding to the second layer,
wherein said upper surface exhibiting an unevenness, and
wherein the second layer having a roughness lower than 10 nm at a surface bonded to the handle.

8. The chip of claim 7, wherein a depth of said unevenness is in a range from 100 to 200 nm.

9. The electronic chip of claim 7, wherein the chip is a back-side illuminated CMOS image sensor.
